(19) United States
(12) Patent Application Publication
(10) Pub. No.: US 2026/0206265 A1
(43) Pub. Date: Jul. 16, 2026

(54) SWITCHING ELEMENT

(71) Applicants: DENSO CORPORATION, Kariya-City (JP); TOYOTA JIDOSHA KABUSHIKI KAISHA, Toyota-Shi (JP); MIRISE Technologies Corporation, Nisshin-Shi (JP)

(72) Inventors: Masaaki HONDA, Nisshin-shi (JP); Ryota SUZUKI, Nisshin-shi (JP)

(21) Appl. No.: 19/445,917

(22) Filed: Jan. 12, 2026

(30) Foreign Application Priority Data
Jan. 14, 2025 (JP) 2025-004961

(51) Int. Cl. H10D 62/10; H10D 30/66; H10D 62/60

(52) U.S. Cl. CPC H10D 62/107; H10D 30/668; H10D 62/126; H10D 62/60

(57) ABSTRACT

A switching element includes a semiconductor substrate, a source electrode covering an upper surface of the semiconductor substrate, and a plurality of gate portions extending in a first direction and arranged at intervals in a direction orthogonal to the first direction. A region between center lines of adjacent gate electrodes is referred to as a unit semiconductor region. The semiconductor substrate includes electric field relaxation regions spaced apart from a body region below the body region, and connection regions. The electric field relaxation regions have linear portions extending across the unit semiconductor regions along a second direction intersecting with the first direction. The linear portions are arranged linearly along the second direction with gaps therebetween so as to form a row unit. The connection regions connect the linear portions to the body region, and one connection region is provided for each electric field relaxation region.

### CROSS REFERENCE TO RELATED APPLICATION

The present application claims the benefit of priority from Japanese Patent Application No. 2025-004961 filed on January 14, 2025. The entire disclosures of the above application are incorporated herein by reference.

### TECHNICAL FIELD

The present disclosure relates to a switching element.

### BACKGROUND

For example, there is a switching element having a plurality of gate portions that extend linearly in a first direction. In a region between the gate portions, an n-type source region, a p-type body region and the like are provided. The switching element has a drift region in contact with each of the body regions from below. The switching element further has a plurality of p-type electric field relaxation regions, that is, electric field blocking layers, arranged within the drift region. Each electric field relaxation region extends linearly in a second direction intersecting with the first direction. Each electric field relaxation region is connected to the body region through a p-type connection region, that is, a p-type deep layer. Each electric field relaxation region is connected to the body region through a plurality of the connection regions dispersed in the second direction. The electric field relaxation region relaxes the electric field applied to a gate insulating film.

### SUMMARY

According to an aspect of the present disclosure, a switching element includes: a semiconductor substrate, a source electrode covering an upper surface of the semiconductor substrate, and a plurality of gate portions. The plurality of gate portions extend in a first direction and are arranged at intervals in a direction orthogonal to the first direction when viewed in a thickness direction of the semiconductor substrate. Each of the plurality of gate portions includes a gate insulating film and a gate electrode disposed on an inner side of the gate insulating film. A region between center lines of adjacent gate electrodes is referred to as a unit semiconductor region. The semiconductor substrate includes: a plurality of source regions of a first conductivity type, each disposed in a corresponding unit semiconductor region and in contact with the source electrode and the gate insulating film; a plurality of body regions of a second conductivity type, each disposed in the corresponding unit semiconductor region and in contact with the source electrode, the gate insulating film, and the source region; a drift region distributed across a plurality of the unit semiconductor regions, the drift region being in contact with the gate insulating film and the body region in each of the unit semiconductor regions and separated from the source region by the body region; a plurality of electric field relaxation regions of the second conductivity type disposed inside the drift region, spaced apart from the body region below the body region, and separated from each other; and a plurality of connection regions of the second conductivity type each connecting a corresponding electric field relaxation region to the body region. The plurality of electric field relaxation regions may have a plurality of linear portions each extending across two or more of the plurality of unit semiconductor regions along a second direction intersecting with the first direction. The plurality of linear portions may be arranged linearly along the second direction with gaps therebetween so as to form a row unit. The plurality of connection regions may connect the plurality of linear portions to the body region, and one connection region may be provided for each of the plurality of electric field relaxation regions.

### BRIEF DESCRIPTION OF DRAWINGS

Objects, features and advantages of the present disclosure will become more apparent from the following detailed description made with reference to the accompanying drawings, in which like parts are designated by like reference numbers and in which:

FIG. 1 is a cross-sectional and perspective view of a switching element according to a first embodiment;

FIG. 2 is a plan view of the switching element for showing the arrangement of trenches and electric field relaxation regions, when viewed in a z direction, according to the first embodiment;

FIG. 3 is a cross-sectional view taken along a line III-III in FIG. 2;

FIG. 4 is a cross-sectional view taken along a line IV-IV in FIG. 2;

FIG. 5 is a cross-sectional view taken along a line V-V in FIG. 2;

FIG. 6 is a circuit diagram of the switching element;

FIG. 7 is a plan view of a switching element for showing the arrangement of trenches and electric field relaxation regions, when viewed in a z direction, according to a second embodiment;

FIG. 8 is a plan view of a switching element for showing the arrangement of trenches and electric field relaxation regions, when viewed in a z direction, according to a first modification;

FIG. 9 is a plan view of a switching element for showing the arrangement of trenches and electric field relaxation regions, when viewed in a z direction, according to a second modification;

FIG. 10 is a cross-sectional view of a switching element according to a third modification;

FIG. 11 is a cross-sectional and perspective view of a switching element according to a fourth modification;

FIG. 12 is a cross-sectional and perspective view of a switching element according to a fifth modification; and

FIG. 13 is a cross-sectional and perspective view of a switching element according to a sixth modification.

### DETAILED DESCRIPTION

When a switching element is turned off, the current flowing through the switching element decreases suddenly, and a surge voltage is applied to the switching element. The present disclosure provides a technique for suppressing a surge voltage in a switching element having an electric field relaxation region.

According to an aspect of the present disclosure, a switching element includes: a semiconductor substrate, a source electrode covering an upper surface of the semiconductor substrate, and a plurality of gate portions that extend in a first direction and are arranged at intervals in a second direction orthogonal to the first direction, when viewed along a thickness direction of the semiconductor substrate. Each of the plurality of gate portions includes a gate insulating film and a gate electrode disposed on an inner side of the gate insulating film. A region defined between center lines of the adjacent gate electrodes is referred to as a unit semiconductor region. The semiconductor substrate includes a plurality of source regions of a first conductivity type, a plurality of body regions of a second conductivity type, a drift region, a plurality of electric field relaxation regions of the second conductivity type, and a plurality of connection regions of the second conductivity type. Each of the source regions is disposed in a corresponding unit semiconductor region and in contact with the source electrode and the gate insulating film. Each of the body regions is disposed in a corresponding unit semiconductor region and is in contact with the source electrode, the gate insulating film, and the source region. The drift region is distributed across a plurality of the unit semiconductor regions, and is in contact with the gate insulating film and the body region in each of the unit semiconductor regions. The drift region is separated from each of the source regions by the body region. The plurality of electric field relaxation regions are disposed inside the drift region. The electric field relaxation regions are arranged below the body region with a gap from the body region, and are separated from each other. The plurality of connection regions connect the electric field relaxation regions to the body region. Each of the plurality of electric field relaxation regions has a linear portion extending across two or more of the plurality of unit semiconductor regions along a second direction intersecting with the first direction. The plurality of linear portions are arranged linearly along the second direction with gaps therebetween so as to form a row unit. The plurality of connection regions connect the plurality of linear portions to the body region, and one connection region is provided for each of the plurality of electric field relaxation regions.

In this specification, one of the first conductivity type and the second conductivity type refers to an n-type, and the other refers to a p-type.

In this specification, the drift region is a region through which current flows when the switching element is on, and which becomes depleted when the switching element is off.

In the switching element described above, the linear portions of the electric field relaxation regions are arranged linearly in the second direction with gaps therebetween so as to form the row unit, and the row unit relaxes the electric field applied to the gate insulating film. In addition, one connection region is provided for each electric field relaxation region. Therefore, the electrical resistance of a current path from the linear portion to the body region is high. Furthermore, in the switching element described above, a capacitance (i.e., a capacitor) is formed between the linear portion and the drain. This capacitance and the electrical resistance described above form a series circuit of capacitance and electrical resistance between a source and a drain of the switching element. This series circuit functions as a snubber circuit, suppressing a surge voltage applied to the switching element. According to such a structure, the surge voltage can be suppressed when the switching element is turned off.

### First Embodiment

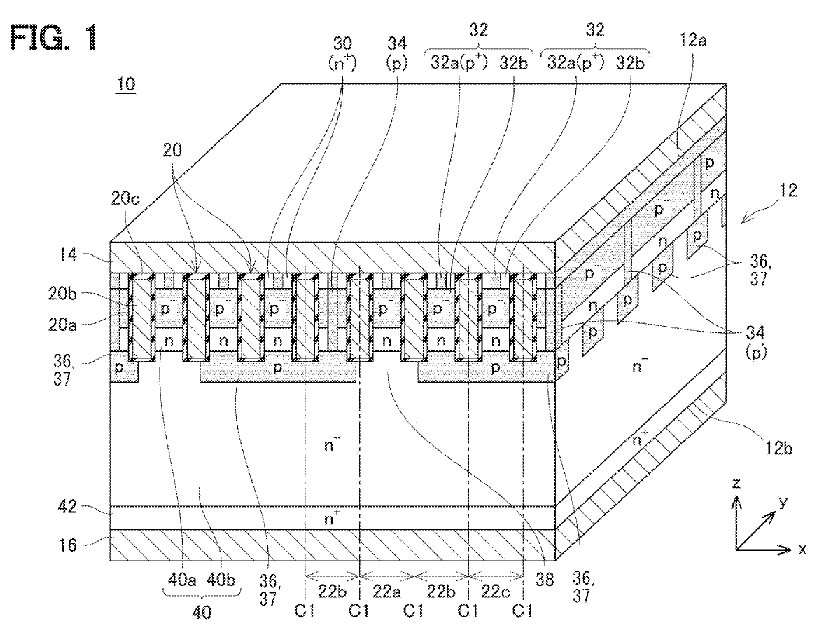

A switching element 10 according to a first embodiment shown in FIG. 1 is a metal oxide semiconductor field effect transistor (MOSFET). The switching element 10 has a semiconductor substrate 12, a source electrode 14, and a drain electrode 16. The semiconductor substrate 12 is made of silicon carbide (SiC). However, the semiconductor substrate 12 may be made of other semiconductor materials such as silicon (Si) or gallium nitride (GaN). The source electrode 14 covers an upper surface 12a of the semiconductor substrate 12. The drain electrode 16 covers a lower surface 12b of the semiconductor substrate 12. Hereinafter, a thickness direction of the semiconductor substrate 12 is referred to as a z direction, a direction within a plane perpendicular to the z direction is referred to as an x direction, and a direction perpendicular to the x direction within the same plane is referred to as a y direction.

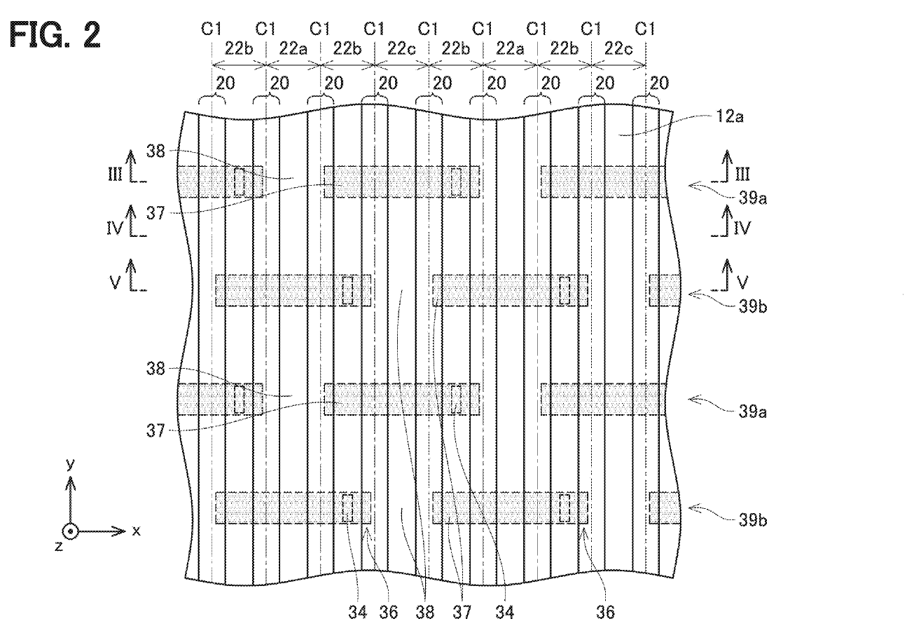

The semiconductor substrate 12 is formed with a plurality of trenches 20 in the upper surface 12a. As shown in FIG. 2, each trench 20 extends linearly in the y direction in the upper surface 12a. The plurality of trenches 20 are arranged at intervals in the x direction. In each figure, a center line C1 indicates the center of the trench 20 in the x direction. In addition, in each figure, a region between the center lines C1 of the adjacent trenches 20 is referred to as a unit semiconductor region 22. The semiconductor substrate 12 has a plurality of the unit semiconductor regions 22. The unit semiconductor regions 22 may be respectively referred to as unit semiconductor regions 22a, 22b, and 22c for convenience.

In each trench 20, a gate insulating film 20a and a gate electrode 20b are disposed. The gate insulating film 20a covers an inner surface of the trench 20. The gate electrode 20b is disposed at a position surrounded by the gate insulating film 20a. The gate electrode 20b is insulated from the semiconductor substrate 12 by the gate insulating film 20a. An upper surface of the gate electrode 20b is covered by an interlayer insulating film 20c. The gate electrode 20b is insulated from the source electrode 14 by the interlayer insulating film 20c. It is also possible to regard the gate insulating film 20a and the interlayer insulating film 20c collectively as the gate insulating film. In this case, the gate electrode 20b can be regarded as being provided inside the gate insulating film.

The semiconductor substrate 12 has a plurality of n-type source regions 30, a plurality of p-type body regions 32, a plurality of p-type electric field relaxation regions 36, a plurality of p-type connection regions 34, an n-type drift region 40, and an n-type drain region 42.

The source region 30 is an n-type region having a high n-type impurity concentration. Two source regions 30 are provided in each unit semiconductor region 22. Each of the source regions 30 is disposed in a range including the upper surface 12a of the semiconductor substrate 12 and is in ohmic contact with the source electrode 14. Each of the source regions 30 is in contact with the gate insulating film 20a at the upper end of a side wall of the corresponding trench 20. Each of the source regions 30 extends linearly in the y direction.

One body region 32 is provided in each unit semiconductor region 22. The body regions 32 may be connected to each other at a position not shown. Each of the body regions 32 has a contact region 32a and a low-concentration body region 32b.

Each contact region 32a is a p-type region having a high p-type impurity concentration. Each contact region 32a is disposed adjacent to the source region 30. Each contact region 32a is disposed in a range including the upper surface 12a of the semiconductor substrate 12, and is in ohmic contact with the source electrode 14. Each contact region 32a extends linearly in the y direction.

The low-concentration body region 32b is a p-type region having a p-type impurity concentration lower than that of the contact region 32a. The low-concentration body region 32b is in contact with the source regions 30 and the contact region 32a from below within the unit semiconductor region 22. The low-concentration body region 32b is connected to the source electrode 14 through the contact region 32a. The low-concentration body region 32b is in contact with the gate insulating film 20a below the source region 30.

The drift region 40 is a region that allows electrons to flow when the switching element is on, and that is depleted when the switching element is off. In the present embodiment, the drift region 40 is an n-type region having an n-type impurity concentration lower than that of the source region 30. The drift region 40 is distributed across the plurality of unit semiconductor regions 22. In the z direction, the drift region 40 is distributed from the position of the lower end of the low-concentration body region 32b to a position below the lower end of each trench 20, more specifically, to a position in the vicinity of the lower surface 12b of the semiconductor substrate 12. The drift region 40 is in contact with the low-concentration body region 32b from below within each unit semiconductor region 22. The drift region 40 is separated from the source region 30 by the low-concentration body region 32b. The drift region 40 is in contact with the gate insulating film 20a below the low-concentration body region 32b within each unit semiconductor region 22.

Each of the electric field relaxation regions 36 is a p-type region having a p-type impurity concentration lower than that of the contact region 32a and higher than that of the low-concentration body region 32b. Each of the electric field relaxation regions 36 is provided inside the drift region 40. Each of the electric field relaxation regions 36 is distributed in the z direction from a position above the lower end of the trench 20 to a position below the lower end of the trench 20. That is, each of the electric field relaxation regions 36 is arranged in a range overlapping with the lower end of the trench 20 in the z direction. Each of the electric field relaxation regions 36 is in contact with the gate insulating film 20a at the lower end of the trench 20. As shown in FIG. 2, the plurality of electric field relaxation regions 36 are arranged dispersedly in the x direction as well as in the y direction.

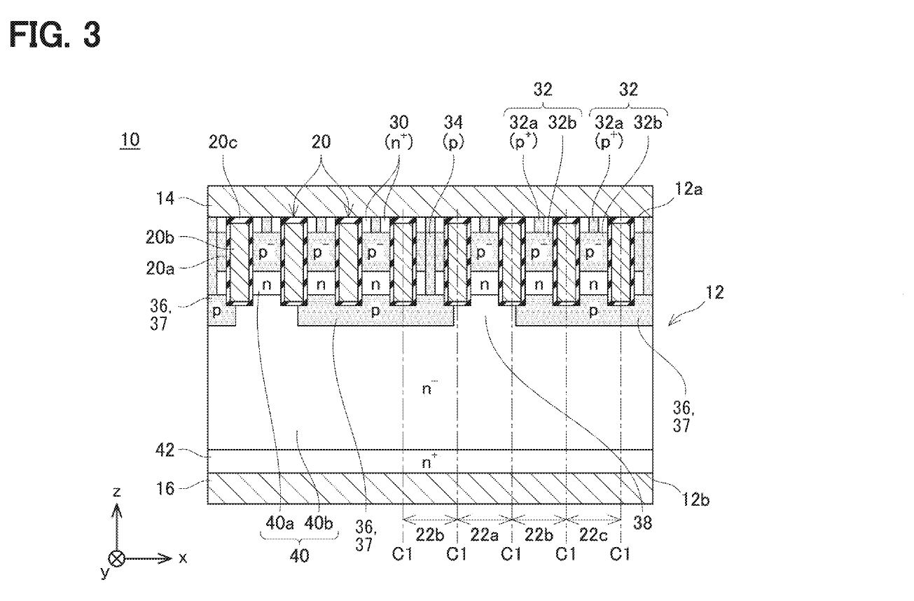

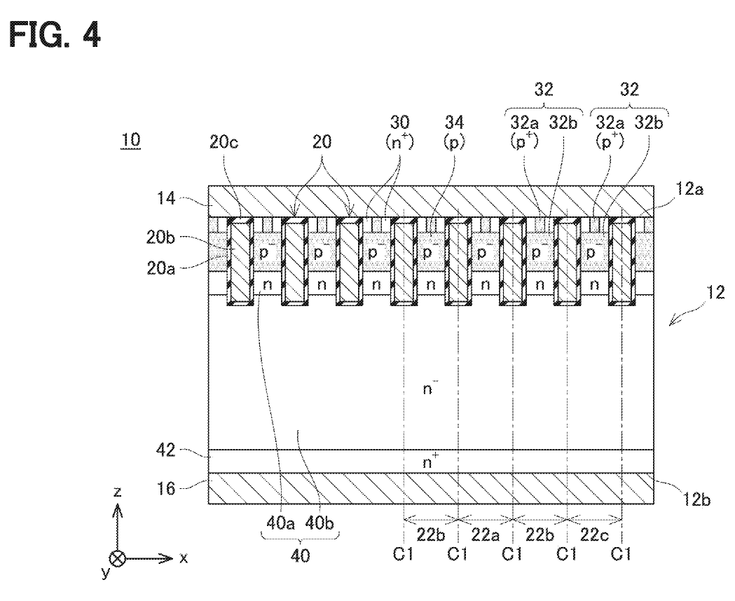

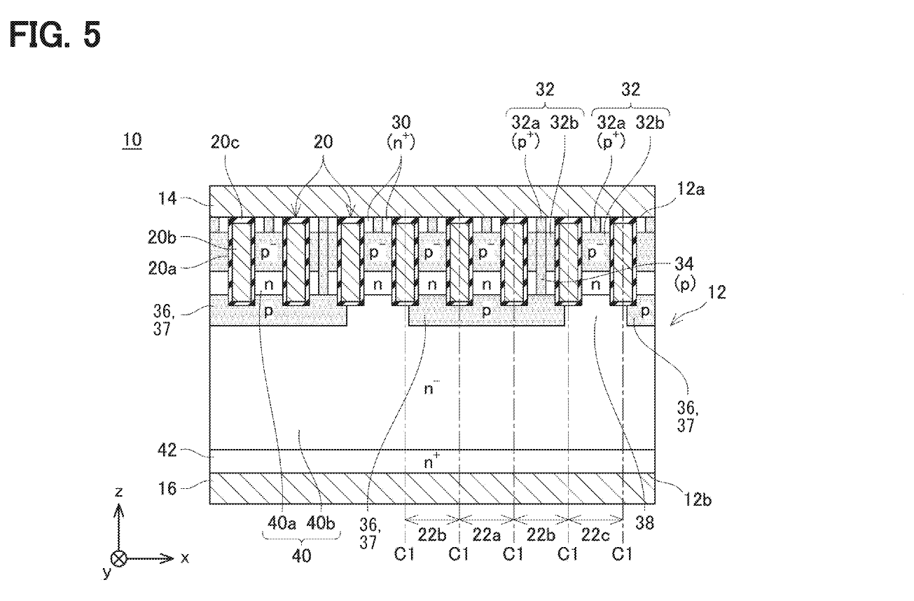

As shown in FIG. 2, each electric field relaxation region 36 is composed of a linear portion 37 that extends linearly in the x direction. Each linear portion 37 is distributed to extend across multiple unit semiconductor regions 22 in the x direction. In the present embodiment, each linear portion 37 is distributed to extend across three unit semiconductor regions 22. A plurality of linear portions 37 are arranged to extend in the x direction with gaps 38 interposed therebetween, thereby forming a row unit 39. A plurality of row units 39 are arranged at intervals in the y direction. The plurality of unit semiconductor regions 22 include first unit semiconductor regions 22a, second unit semiconductor regions 22b, and third unit semiconductor regions 22c. The unit semiconductor regions 22 are provided repeatedly in a pattern in which the first unit semiconductor region 22a, the second unit semiconductor region 22b, the third unit semiconductor region 22c, and the second unit semiconductor region 22b are arranged in this order in the x direction, such as from the left side in FIG. 2. The plurality of row units 39 include first row units 39a and second row units 39b. The positions of the gaps 38 between the linear portions 37 are different between the first row unit 39a and the second row unit 39b. As shown in FIGS. 2 and 3, the first row unit 39a has the gaps 38 at the first unit semiconductor regions 22a. That is, each linear portion 37 of the first row unit 39a is distributed in the third unit semiconductor region 22c and the second unit semiconductor regions 22b on both sides of the third unit semiconductor region 22c in the x direction. As shown in FIGS. 2 and 5, the second row unit 39b has the gaps 38 at the third unit semiconductor regions 22c. That is, each linear portion 37 of the second row unit 39b is distributed in the first unit semiconductor region 22a and the second unit semiconductor regions 22b on both sides of the first unit semiconductor region 22a in the x direction. As shown in FIG. 2, the first row unit 39a and the second row unit 39b are alternately arranged at intervals in the y direction. In the first unit semiconductor region 22a, the gap 38 of the first row unit 39a and the linear portion 37 of the second row unit 39b are alternately arranged in the y direction. In the second unit semiconductor region 22b, the linear portion 37 of the first row unit 39a and the linear portion 37 of the second row unit 39b are alternately arranged in the y direction. In the third unit semiconductor region 22c, the linear portion 37 of the first row unit 39a and the gap 38 of the second row unit 39b are alternately arranged in the y direction. As shown in FIGS. 2 and 4, no electric field relaxation region 36 is provided in the space between the first row unit 39a and the second row unit 39b.

As shown in FIG. 1, each of the connection regions 34 is a p-type region having a p-type impurity concentration lower than that of the contact region 32a and higher than that of the low-concentration body region 32b. Each of the connection regions 34 is disposed above a corresponding linear portion 37 to connect the corresponding linear portion 37 to the body region 32 located above. In the present embodiment, the connection region 34 connects the linear portion 37 and the contact region 32a. As another example, the connection region 34 may connect the linear portion 37 and the low-concentration body region 32b. As described above, since the body region 32 is connected to the source electrode 14, the linear portion 37 is connected to the source electrode 14 through the connection region 34 and the body region 32. Therefore, the linear portion 37 has substantially the same potential as the source electrode 14. One connection region 34 is provided for each linear portion 37 (i.e., electric field relaxation region 36). As described above, each linear portion 37 is distributed across the plurality of unit semiconductor regions 22 in the x direction. As shown in FIG. 2, each connection region 34 is disposed in the unit semiconductor region 22 other than the central unit semiconductor region 22, among the unit semiconductor regions 22 in which the corresponding linear portion 37 is provided. In the present embodiment, each connection region 34 is disposed in the outermost unit semiconductor region 22, among the unit semiconductor regions 22 in which the corresponding linear portion 37 is provided. In the first row unit 39a, the connection region 34 is disposed in the second unit semiconductor region 22b, which is on the right side of the third unit semiconductor region 22c. In the second row unit 39b, the connection region 34 is disposed in the second unit semiconductor region 22b, which is on the right side of the first unit semiconductor region 22a.

As shown in FIG. 1, the drift region 40 includes a high-concentration drift region 40a and a low-concentration drift region 40b. The high-concentration drift region 40a has an n-type impurity concentration higher than an n-type impurity concentration of the low-concentration drift region 40b. The high-concentration drift region 40a is disposed at a position higher than the upper surface of each electric field relaxation region 36. That is, the high-concentration drift region 40a is disposed in a region sandwiched between the trenches 20. The high-concentration drift region 40a is in contact with the low-concentration body region 32b from below. The high-concentration drift region 40a is in contact with the gate insulating film 20a below the low-concentration body region 32b. The high-concentration drift region 40a is in contact with the upper surface of each electric field relaxation region 36.

The low-concentration drift region 40b is disposed below the high-concentration drift region 40a. The low-concentration drift region 40b is provided in the gaps between the electric field relaxation regions 36 and in a region below the lower surfaces of the electric field relaxation regions 36. The low-concentration drift region 40b is in contact with the side surfaces and lower surfaces of the electric field relaxation regions 36.

The drain region 42 is an n-type region having an n-type impurity concentration higher than that of the drift region 40. The drain region 42 is disposed below the drift region 40 and is in contact with the drift region 40. The drain region 42 is in ohmic contact with the drain electrode 16 at the lower surface 12b of the semiconductor substrate 12.

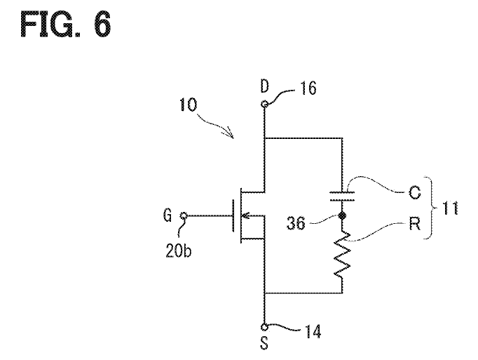

FIG. 6 shows a circuit diagram of the switching element 10. In FIG. 6, terminals G, D, and S represent the gate electrode 20b, the drain electrode 16, and the source electrode 14, respectively. Further, in FIG. 6, a point 36 represents the electric field relaxation region 36. In the switching element 10, as shown in FIG. 6, a capacitance C exists between the electric field relaxation region 36 and the drain electrode 16, and a resistance R exists between the electric field relaxation region 36 and the source electrode 14.

Each electric field relaxation region 36 faces the drain region 42 through the drift region 40. Accordingly, when the drift region 40 is depleted, the capacitance C is formed between each electric field relaxation region 36 and the drain region 42.

The resistance R is an electrical resistance between each electric field relaxation region 36 and the source electrode 14. As described above, each electric field relaxation region 36 is connected to the source electrode 14 through one connection region 34. Further, each electric field relaxation region 36 has the linear portion 37 that extends across the plurality of unit semiconductor regions 22 in the x direction. Accordingly, the electrical resistance of the current path from the end of the linear portion 37 on a further side from the connection region 34 to the source electrode 14 through the connection region 34 is high. For this reason, the electric field relaxation region 36 and the source electrode 14 are connected through this resistance R, which has a relatively high resistance value. As shown in FIG. 6, the capacitance C and the resistance R are connected in series between the source and the drain of the switching element 10. The capacitance C and the resistance R form a snubber circuit 11.

Next, the operation of the switching element 10 will be explained. The switching element 10 is used in a state where the drain electrode 16 is applied with a higher potential than that of the source electrode 14. When a potential equal to or higher than a gate threshold is applied to the gate electrode 20b, a channel is formed in an area of the body region 32 adjacent to the gate insulating film 20a. The source region 30 and the drift region 40 are connected through the channel. As a result, electrons flow from the source electrode 14 to the drift region 40 through the source region 30 and the channel. In the drift region 40, the electrons flow from the upper side of the electric field relaxation regions 36 to the lower side of the electric field relaxation regions 36 through the gaps between the electric field relaxation regions 36. The electrons flow through the drift region 40 to the bottom end and then flow to the drain electrode 16 through the drain region 42. This flow of electrons causes a flow of current from the drain electrode 16 to the source electrode 14. That is, the switching element 10 is turned on. In the present embodiment, since the portion of the drift region 40 sandwiched between the trenches 20 is made of the high-concentration drift region 40a, the resistance of the drift region 40 is low in this portion. Therefore, the on-voltage of the switching element 10 is low.

When the potential of the gate electrode 20b is reduced to a value below the gate threshold, the channel disappears and the current stops. That is, the switching element 10 is turned off. When the switching element 10 is turned off, the potential of the drift region 40 rises. Since the body region 32 has substantially the same potential as the source electrode 14, when the potential of the drift region 40 rises, a reverse voltage is applied to the pn junction at the interface between the body region 32 and the drift region 40. Therefore, a depletion layer spreads from the body region 32 to the drift region 40. Further, since the electric field relaxation region 36 is connected to the source electrode 14 through the connection region 34, the electric field relaxation region 36 has substantially the same potential as the source electrode 14. Therefore, when the potential of the drift region 40 rises, the reverse voltage is also applied to the pn junction at the interface between the electric field relaxation region 36 and the drift region 40. Accordingly, a depletion layer spreads from the electric field relaxation region 36 into the drift region 40. In this way, when the switching element 10 is turned off, the depletion layer spreads from the body region 32 and the electric field relaxation region 36 to the drift region 40. Since the depletion layer spreads from the electric field relaxation region 36 to the drift region 40, the electric field generated at the lower end of the trench 20 is suppressed. In particular, since the electric field relaxation region 36 has approximately the same potential as the source electrode 14, the electric field generated at the lower end of the trench 20 is effectively suppressed. This suppresses the electric field from concentrating on the gate insulating film 20a covering the lower end of the trench 20.

In addition, in the switching element 10, since the electric field relaxation region 36 is provided below the gate electrode 20b, the capacitance (i.e., feedback capacitance) between the gate electrode 20b and the drain electrode 16 is reduced. Therefore, the switching element 10 can perform switching at high speed.

When the switching element 10 is turned off, the current flowing through the switching element 10 decreases suddenly, so a surge voltage is applied to the switching element 10 due to the influence of a parasitic inductance of a peripheral circuit. However, the surge voltage applied to the switching element 10 is suppressed by the snubber circuit 11. As a result, the switching element 10 is protected from excessively high surge voltages. In particular, in the switching element 10 of the first embodiment, the electric field relaxation regions 36 are provided separately in the x direction, and one connection region 34 is provided for each electric field relaxation region 36, thereby increasing the resistance R between the electric field relaxation region 36 and the source electrode 14. Therefore, the surge voltage is effectively suppressed by the snubber circuit 11 formed by the capacitance C and resistance R.

As described above, according to the switching element of the first embodiment, the electric field relaxation region 36 can suppress the electric field concentration on the gate insulating film 20a and can also suppress the surge voltage.

In the first embodiment, the connection region 34 is provided in the unit semiconductor region 22 that is not at the center of the linear portion 37. Alternatively, the connection region 34 may be provided in the unit semiconductor region 22 at the center of the linear portion 37. Even with this configuration, the electrical resistance value of the resistance R can be made higher than in a prior art. However, in a case where the connection region 34 is provided in the unit semiconductor region 22 that is not at the center of the linear portion 37, as in the first embodiment, the electrical resistance value of the resistance R can be made even higher.

### Second Embodiment

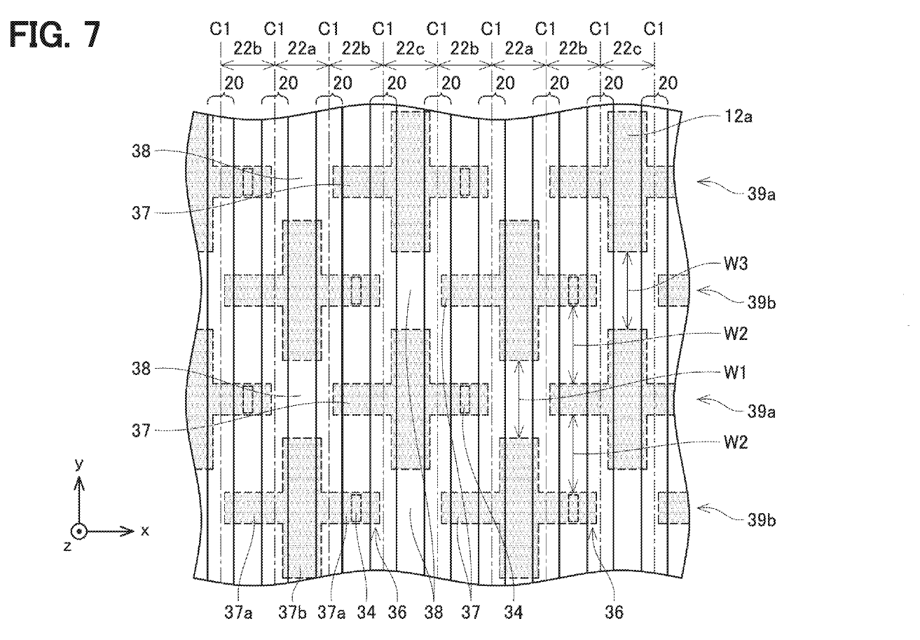

In the switching element of a second embodiment shown in FIG. 7, each linear portion 37 has a narrow portion 37a and a wide portion 37b. The wide portion 37b has a width in the y direction greater than a width of the narrow portion 37a in the y direction. Except for the configuration that each linear portion 37 has the narrow portion 37a and the wide portion 37b, the switching element of the second embodiment is the same as the switching element of the first embodiment.

As shown in FIG. 7, the wide portion 37b protrudes relative to the narrow portion 37a on both sides in the y direction (that is, in the +y direction and the -y direction). The wide portion 37b is provided in the unit semiconductor region 22 located at the center of the linear portion 37 in the x direction. That is, in the first row unit 39a, the wide portion 37b is disposed in the third unit semiconductor region 22c, and the narrow portion 37a is disposed in the second unit semiconductor region 22b. In the second row unit 39b, the wide portion 37b is disposed in the first unit semiconductor region 22a, and the narrow portion 37a is disposed in the second unit semiconductor region 22b. Accordingly, in the first unit semiconductor region 22a, the gap 38 of the first row unit 39a and the wide portion 37b of the second row unit 39b are alternately arranged in the y direction. In the second unit semiconductor region 22b, the narrow portion 37a of the first row unit 39a and the narrow portion 37a of the second row unit 39b are alternately arranged in the y direction. In the third unit semiconductor region 22c, the wide portion 37b of the first row unit 39a and the gap 38 of the second row unit 39b are alternately arranged in the y direction.

According to this configuration, since each wide portion 37b protrudes toward the adjacent gap 38 in the y direction, the gap 38 is easily depleted when the switching element is turned off. In this configuration, therefore, a breakdown voltage of the switching element is further improved. In particular, in the second embodiment, a spacing W1 in the y direction between the wide portions 37b of the second row units 39b within the first unit semiconductor region 22a, a spacing W2 in the y direction between the narrow portion 37a of the first row unit 39a and the narrow portion 37a of the second row unit 39b within the second unit semiconductor region 22b, and a spacing W3 in the y direction between the wide portions 37b of the first row units 39a within the third unit semiconductor region 22c are approximately equal to each other. More specifically, the spacings W1, W2, and W3 are distributed within a range of ±10% of an average value thereof. As a result, in each of the spacings W1, W2, and W3, the drift region 40 is depleted approximately uniformly. Therefore, the electric field concentration is less likely to occur, and the breakdown voltage of the switching element is further improved.

The following describes modifications of the first and second embodiments.

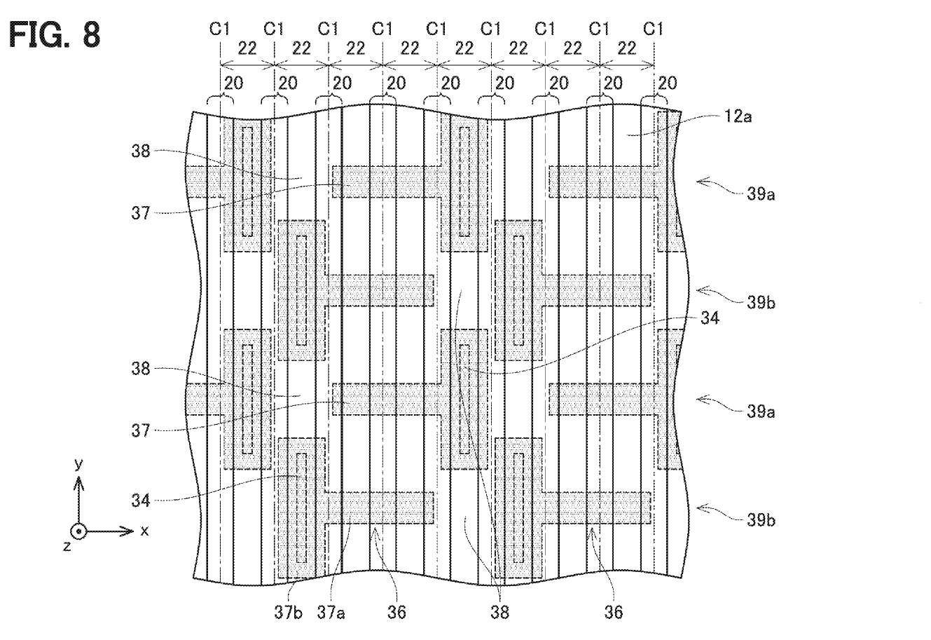

In a case where the linear portion 37 has the wide portion 37b, as shown in FIG. 8, the wide portion 37b may be disposed at the end of the linear portion 37. Further, as shown in FIG. 8, the connection region 34 may be disposed at the wide portion 37b.

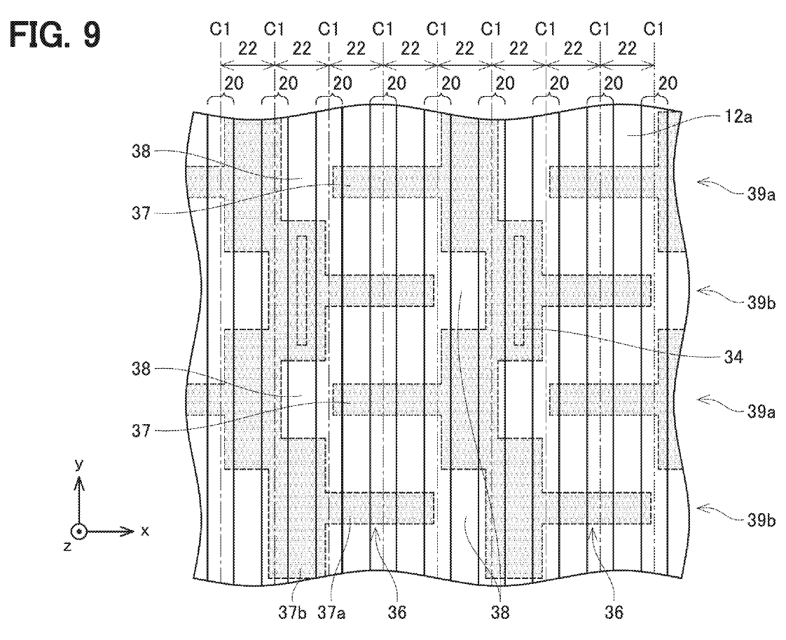

In a case where the linear portion 37 has the wide portion 37b, as shown in FIG. 9, the wide portions 37b may be connected to each other between the row units 39 in the y direction. In this case, the plurality of linear portions 37 connected in the y direction constitute a single electric field relaxation region 36. Also in this case, one connection region 34 can be provided for each electric field relaxation region 36.

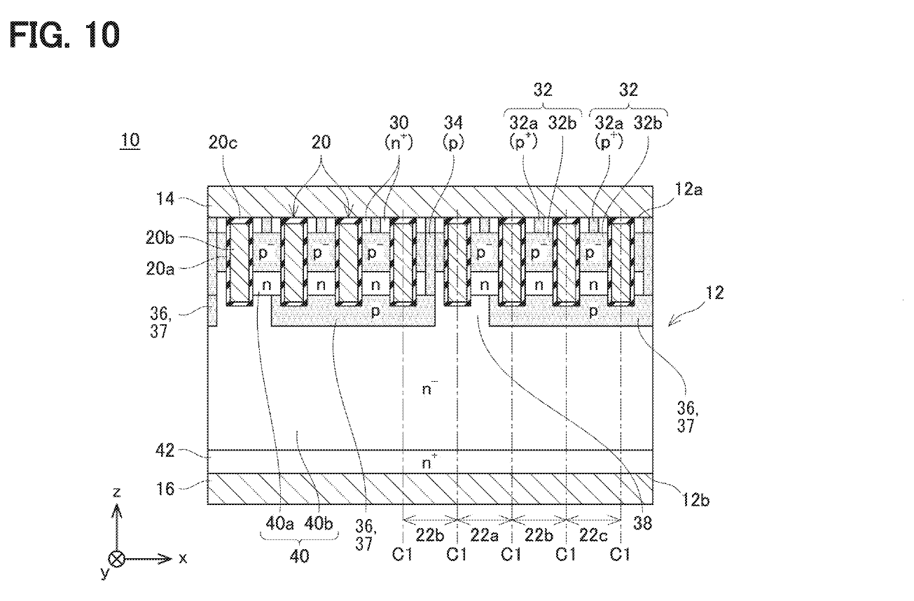

In the first and second embodiments, the ends of each linear portion 37 in the x direction are located at the bottom of the trenches 20. Alternatively, as shown in FIG. 10, the ends of each linear portion 37 in the x direction may be located at positions offset from the trenches 20.

In the first and second embodiments, the drift region 40 includes the high-concentration drift region 40a and the low-concentration drift region 40b. Alternatively, the drift region 40 may be made of an n-type region of a single concentration.

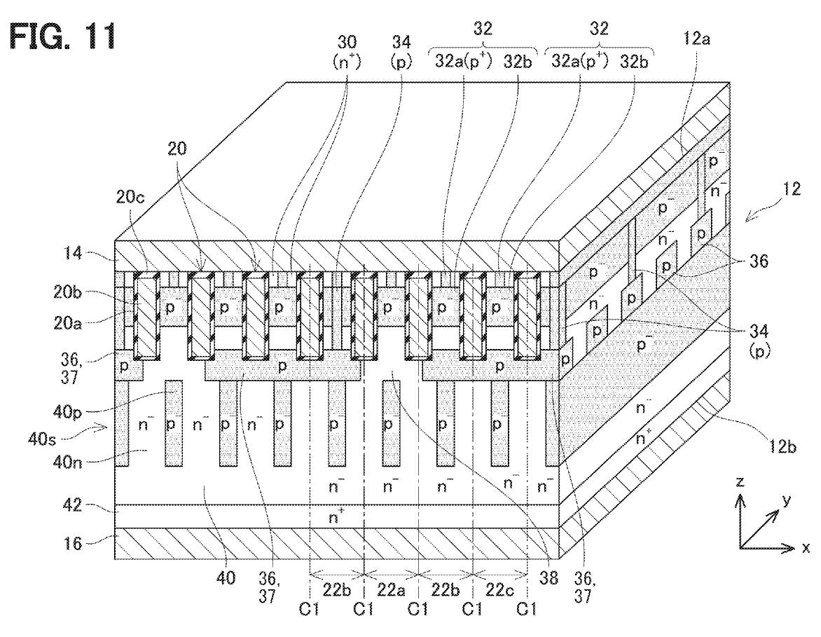

As shown in FIG. 11, the drift region 40 below the electric field relaxation regions 36 may have a super junction layer 40s. The super junction layer 40s has a structure in which n-type regions 40n and p-type regions 40p are alternately arranged in a lateral direction (that is, in a direction perpendicular to the thickness direction of the semiconductor substrate 12). Each p-type region 40p extends linearly in the y direction, and has an upper end connected to the electric field relaxation regions 36. Above and below the super junction layer 40s, the drift region 40 is made of an n-type region 40n. This configuration can improve the breakdown voltage of the switching element.

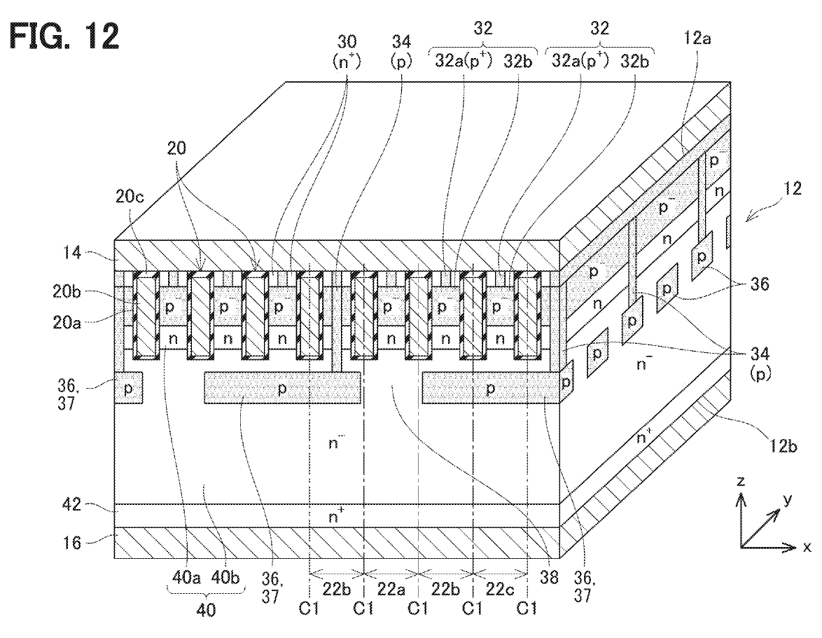

In the first and second embodiments, the electric field relaxation region 36 is disposed at the depth overlapping with the lower end of the trench 20. Alternatively, as shown in FIG. 12, the electric field relaxation region 36 may be disposed at a depth lower than the lower end of the trench 20.

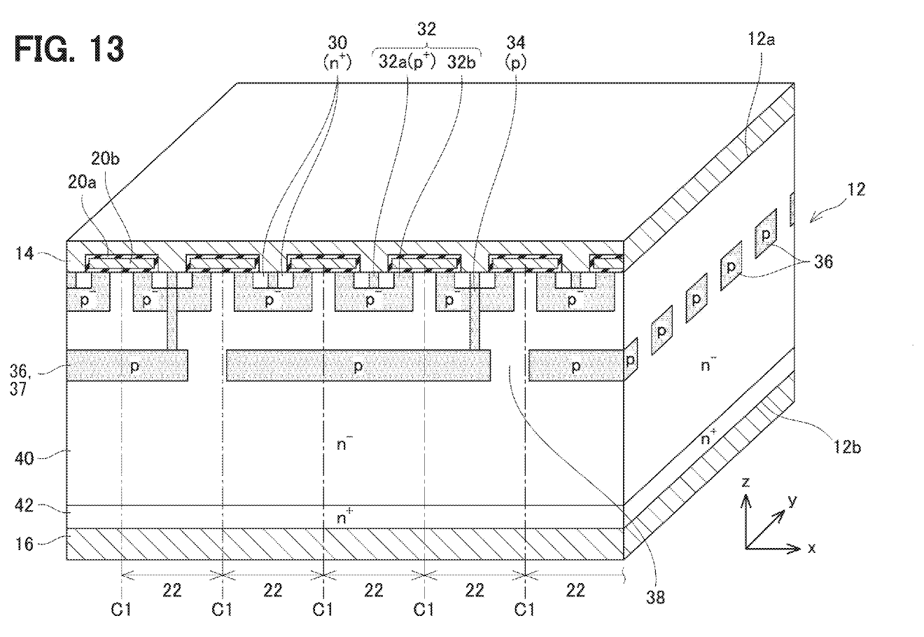

In the first and second embodiments, the gate portion is of the trench type. Alternatively, as shown in FIG. 13, the gate portion may be of a planar type. In FIG. 13, each gate electrode 20b extends linearly in the y direction. Also in this configuration, by arranging the linear portion 37 so as to extend across the plurality of unit semiconductor regions 22 sectioned by the center lines C1 of the respective gate electrodes 20b, and by providing the connection region 34 for each electric field relaxation region 36, it is possible to increase the resistance R between the electric field relaxation region 36 and the source electrode 14 and to suppress the surge voltage.

In the first and second embodiments, when viewed along the thickness direction of the semiconductor substrate 12, the linear portions 37 and the row units 39 extended in a direction orthogonal to the gate electrodes 20b. However, the linear portions 37 and the row units 39 may extend in a direction that obliquely intersects with the gate electrodes 20b.

The techniques disclosed by the present disclosure will be summarized as follows.

### Configuration 1

A switching element includes: a semiconductor substrate; a source electrode covering an upper surface of the semiconductor substrate; and a plurality of gate portions extending in a first direction and arranged at intervals in a direction orthogonal to the first direction when viewed in a thickness direction of the semiconductor substrate. Each of the plurality of gate portions includes a gate insulating film and a gate electrode disposed on an inner side of the gate insulating film. A region between center lines of adjacent gate electrodes is referred to as a unit semiconductor region. The semiconductor substrate includes: a plurality of source regions of a first conductivity type, each disposed in a corresponding unit semiconductor region and in contact with the source electrode and the gate insulating film; a plurality of body regions of a second conductivity type, each disposed in the corresponding unit semiconductor region and in contact with the source electrode, the gate insulating film, and the source region; a drift region distributed across a plurality of the unit semiconductor regions, the drift region being in contact with the gate insulating film and the body region in each of the unit semiconductor regions and separated from the source region by the body region; a plurality of electric field relaxation regions of the second conductivity type disposed inside the drift region, spaced apart from the body region below the body region, and separated from each other; and a plurality of connection regions of the second conductivity type each connecting a corresponding electric field relaxation region to the body region. The plurality of electric field relaxation regions have a plurality of linear portions extending across the plurality of unit semiconductor regions along a second direction intersecting with the first direction. The plurality of linear portions are arranged linearly along the second direction with gaps therebetween so as to form a row unit. The plurality of connection regions connect the plurality of linear portions to the body region, and one connection region is provided for each of the plurality of electric field relaxation regions.

### Configuration 2

In the switching element as in the configuration 1, the plurality of linear portions are arranged so as to form a plurality of the row units spaced apart from each other in the first direction.

### Configuration 3

In the switching element as in the configuration 2, the plurality of row units includes a first row unit and a second row unit alternately arranged in the first direction.

Each of the plurality of linear portions has a narrow portion and a wide portion having a width in the first direction greater than a width of the narrow portion in the first direction. The plurality of unit semiconductor regions includes a first unit semiconductor region, a second unit semiconductor region, and a third unit semiconductor region. In the first unit semiconductor region, the gap of the first row unit and the wide portion of the second row unit are alternately arranged in the first direction. In the second unit semiconductor region, the narrow portion of the first row unit and the narrow portion of the second row unit are alternately arranged in the first direction. In the third unit semiconductor region, the wide portion of the first row unit and the gap of the second row unit are alternately arranged in the first direction.

### Configuration 4

In the switching element as in the configuration 3, a spacing in the first direction between the wide portions of the second row units in the first unit semiconductor region, a spacing in the first direction between the narrow portion of the first row unit and the narrow portion of the second row unit in the second unit semiconductor region, and a spacing in the first direction between the wide portions of the first row unit in the third unit semiconductor region have values that are within ±10% of an average value thereof.

### Configuration 5

In the switching element as in any one of the configurations 1 to 4, each of the plurality of connection regions is disposed in the unit semiconductor region that is not a central unit semiconductor region disposed at a center among the plurality of unit semiconductor regions in which the corresponding linear portion is present.

### Configuration 6

In the switching element as in any one of the configurations 1 to 5, the semiconductor substrate is formed with a plurality of trenches extending in the first direction at the upper surface. The gate insulating film covers an inner surface of each of the plurality of trenches, and the gate electrode is disposed inside of each of the plurality of trenches.

### Configuration 7

In the switching element as in any one of the configurations 1 to 6, the drift region is a region of the first conductivity type.

### Configuration 8

In the switching element as in the configuration 7, the drift region includes a high-concentration first conductivity type region above the plurality of electric field relaxation regions, and a low-concentration first conductivity type region below the plurality of electric field relaxation regions, the low-concentration first conductivity type region having a first conductivity type impurity concentration lower than that of the high-concentration first conductivity type region.

### Configuration 9

In the switching element as in any one of the configurations 1 to 6, a part of the drift region above the plurality of electric field relaxation regions is a region of the first conductivity type, and a part of the drift region below the plurality of electric field relaxation regions includes a super junction layer in which a region of the first conductivity type and a region of the second conductivity type are alternately arranged in a lateral direction of the semiconductor substrate.

According to the configurations 2 to 4, electric field concentration can be effectively suppressed.

According to the configuration 5, since the electrical resistance of the current path from the linear portion to the body region becomes higher, surge voltage can be suppressed more effectively.

According to the configuration 6, electric field concentration in the gate insulating film covering the lower end of the trench can be suppressed.

According to the configuration 8, the on-resistance of the switching element can be reduced.

According to the configuration 9, the breakdown voltage of the switching element can be improved.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A switching element comprising,
a semiconductor substrate;
a source electrode covering an upper surface of the semiconductor substrate; and
a plurality of gate portions extending in a first direction and arranged at intervals in a direction orthogonal to the first direction when viewed in a thickness direction of the semiconductor substrate, wherein
each of the plurality of gate portions includes a gate insulating film and a gate electrode disposed on an inner side of the gate insulating film,
a region between center lines of adjacent gate electrodes is referred to as a unit semiconductor region,
the semiconductor substrate includes:
a plurality of source regions of a first conductivity type, each disposed in a corresponding unit semiconductor region and in contact with the source electrode and the gate insulating film;
a plurality of body regions of a second conductivity type, each disposed in the corresponding unit semiconductor region and in contact with the source electrode, the gate insulating film, and the source region;
a drift region distributed across a plurality of the unit semiconductor regions, the drift region being in contact with the gate insulating film and the body region in each of the unit semiconductor regions and separated from the source region by the body region;
a plurality of electric field relaxation regions of the second conductivity type disposed inside the drift region, spaced apart from the body region below the body region, and separated from each other; and
a plurality of connection regions of the second conductivity type each connecting a corresponding electric field relaxation region to the body region,
the plurality of electric field relaxation regions have a plurality of linear portions each extending across two or more of the plurality of unit semiconductor regions along a second direction intersecting with the first direction,
the plurality of linear portions are arranged linearly along the second direction with gaps therebetween so as to form a row unit,
the plurality of connection regions connect the plurality of linear portions to the body region, and
one connection region is provided for each of the plurality of electric field relaxation regions.

2. The switching element according to claim 1, wherein
the plurality of linear portions are arranged so as to form a plurality of the row units spaced apart from each other in the first direction.

3. The switching element according to claim 2, wherein
the plurality of row units includes a first row unit and a second row unit alternately arranged in the first direction,
each of the plurality of linear portions has a narrow portion and a wide portion having a width in the first direction greater than a width of the narrow portion in the first direction,
the plurality of unit semiconductor regions includes a first unit semiconductor region, a second unit semiconductor region, and a third unit semiconductor region,
in the first unit semiconductor region, the gap of the first row unit and the wide portion of the second row unit are alternately arranged in the first direction,
in the second unit semiconductor region, the narrow portion of the first row unit and the narrow portion of the second row unit are alternately arranged in the first direction, and
in the third unit semiconductor region, the wide portion of the first row unit and the gap of the second row unit are alternately arranged in the first direction.

4. The switching element according to claim 3, wherein
a spacing in the first direction between the wide portions of the second row units in the first unit semiconductor region, a spacing in the first direction between the narrow portion of the first row unit and the narrow portion of the second row unit in the second unit semiconductor region, and a spacing in the first direction between the wide portions of the first row unit in the third unit semiconductor region have values that are within ±10% of an average value thereof.

5. The switching element according to claim 1, wherein
each of the plurality of connection regions is disposed in the unit semiconductor region that is not a central unit semiconductor region disposed at a center among the two or more of the plurality of unit semiconductor regions in which the corresponding linear portion is present.

6. The switching element according to claim 1, wherein
the semiconductor substrate is formed with a plurality of trenches extending in the first direction at the upper surface,
the gate insulating film covers an inner surface of each of the plurality of trenches, and
the gate electrode is disposed inside of each of the plurality of trenches.

7. The switching element according to claim 1, wherein
the drift region is a region of the first conductivity type.

8. The switching element according to claim 7, wherein
the drift region includes a high-concentration first conductivity type region above the plurality of electric field relaxation regions, and a low-concentration first conductivity type region below the plurality of electric field relaxation regions, the low-concentration first conductivity type region having a first conductivity type impurity concentration lower than that of the high-concentration first conductivity type region.

9. The switching element according to claim 1, wherein
a part of the drift region above the plurality of electric field relaxation regions is a region of the first conductivity type, and
a part of the drift region below the plurality of electric field relaxation regions includes a super junction layer in which a region of the first conductivity type and a region of the second conductivity type are alternately arranged in a lateral direction of the semiconductor substrate.
